(19) United States
(12) Patent Application Publication
(10) Pub. No.: US 2005/0053869 A1
(43) Pub. Date: Mar. 10, 2005

(54) Methods and compositions for selectively etching metal films and structures

(76) Inventor: Justin K. Brask, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/658,225

(22) Filed: Sep. 8, 2003

(51) Int. Cl. G03F 7/30; G03F 7/42

(52) U.S. Cl. 430/318; 216/100; 430/313

(57) ABSTRACT

A method for selectively etching metal and metal-based films during integrated circuit fabrication. For one embodiment known chelators, which may be in relatively high concentration are used to etch metal films. In various alternative embodiments new chelators, developed by tailoring known chelators to target specific metals, are used to etch metal films. A metallic film is deposited on a substrate, the metallic film containing one or more specific metals. A layer of photoresist is deposited on the metallic film and patterned to mask a desired portion of the metallic film while exposing an undesired portion of the metallic film. One or more chelating agents are selected based upon the one or more specific metals contained in the metallic film and used to remove the undesired portion of the metallic film.

### FIELD

Embodiments of the invention relate generally to the manufacture of integrated circuit (IC) devices and more specifically to methods and compositions for selectively etching the metal films and other metal structures of such devices.

### BACKGROUND

Manufacturers are employing metal layers more and more often in IC devices. Copper has been used for some time in backend processing (e.g., interconnects) and there is a continuing trend of some manufacturers toward metals for frontend processing (transistor fabrication) as well. For example, in the manufacture of CMOS transistors, metal may be used for the gate electrode. Metal has advantages over more traditional materials (e.g., polysilicon). Metal provides for much better current flow than polysilicon with substantially reduced voltage depletion problems. Metal gate electrodes eliminate the polydepletion exhibited by polysilicon gates, which effectively increases the gate dielectric thickness. Metals (as metal oxides) are also being used to replace or enhance conventional materials as gate dielectrics. Metal-oxide films can provide a relatively thin, high-capacitance, dielectric as compared with conventional materials used for the gate dielectric (silicon dioxide).

The difficulty with this move toward the use of metals in frontend processing lies in forming the metal (or metal-based) material into the desired structure. For decades IC device manufacturers have perfected processes depositing and patterning silicon based materials (e.g., silicon-nitrides, silicon-oxides, polysilicon, etc). The shift to metal films will require some dramatic changes in some manufacturing processes, especially in regard to film patterning chemistries.

FIG. 1 illustrates a process by which a film is etched in accordance with the prior art. A substrate 101, which may be a silicon wafer, has a film (e.g., a silicon-based film) 102 deposited upon it. Typically, in creating structures, a film is blanket-deposited, then a photo resist is deposited and patterned through a lithography process. FIG. 1 shows patterned photoresist 103 on film 102. The patterned photoresist 103 covers the desired portion of the film 102 used to create various structures on the wafer. At this point, a chemical etching process is typically used to remove those portion of the film not covered by the photoresist leaving etched film 102a. The patterned photoresist 102 is then removed.

Typical chemical etching processes include plasma etching, wet chemical etching, and dry (non-plasma) chemical etching. Each of which may provide satisfactory results for etching silicon-based films, but have distinct disadvantages in their application to metal and metal-based films.

Plasma etching uses a charged gas to bombard the targeted portions of the film with ionized molecules. The targeted portions are disintegrated by the ion bombardment while the photoresist protects the desired areas. This works well for silicon-based films because the atoms of silicon broken off from the targeted portions by the ion bombardment form very volatile byproducts. For example, if the silicon is etched with a fluoride plasma, the silicon atoms form silicon-tetra-fluoride, which is a volatile molecule that can be removed efficiently and effectively using a vacuum. In contrast, where plasma etching has been used to etch metal films, the displaced metal atoms from the targeted portion of the film, can, depending on the metal, form a solid complex. In such cases the metal is sputtered and redeposited elsewhere on the wafer.

Wet chemistry etching typically involves a corrosive in a solution used to etch the targeted portions of the film. The silicon-based films can be etched with a chemistry having relatively mild conditions (e.g., temperature, pH, concentrations, etc.). To etch metal and metal-based films the conditions of the chemistry have to be much more extreme. For example, to etch the metal a “piranha” etch (e.g., a sulfuric acid combination) may be required or where silicon could be etched at room temperature, the metal film may require temperatures in excess of 120° C. The problem with such corrosive compounds, or elevated temperatures, is that selectivity is sacrificed. It is impossible to retain other desired films or structures on the wafer while etching the metal film.

Dry chemistry etching which uses a (non-ionized) gas to react with the film exhibits the same problems as wet chemistry etching for metal films. That is, it doesn't work effectively unless the chemistry conditions are more extreme at which point there may be detrimental impact on other desired films or structures. For example, for silicon-based films, a chemistry using something fairly mild such as sulfur hexa-fluoride may suffice. For metal films it may be necessary to add other more corrosive components (e.g., hydrogen bromide and a fluorocarbon species). The various combination employed to etch the metal have detrimental effects on other films on the wafer. That is, in etching the metal other desired films and structures are destroyed or degraded.

There is not presently an etch process that provides efficient selective etching of metal and metal-based films.

### BRIEF DESCRIPTION OF THE DRAWINGS

The invention may be best understood by referring to the following description and accompanying drawings that are used to illustrate embodiments of the invention. In the drawings:

FIG. 1 illustrates a process by which a film is etched in accordance with the prior art;

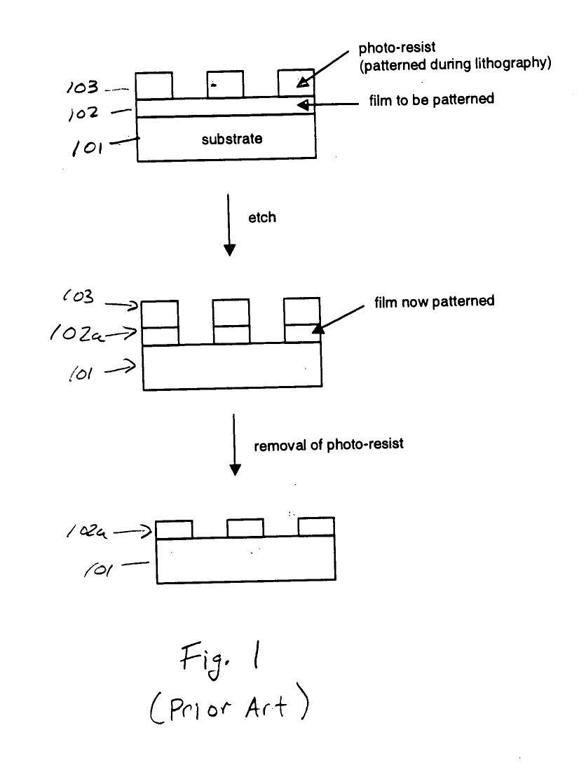

FIG. 2 illustrates a process for etching metal and metal-based films in accordance with one embodiment of the invention;

FIGS. 3A-3C illustrate various types of hexa-dentate chelating agents; and

FIG. 4 illustrates a process in which a metal film is etched using one or more chelating agents in accordance with one embodiment of the invention.

### DETAILED DESCRIPTION

Overview

Embodiments of the invention provide methods for selectively etching metal and metal-based films. For one embodiment known chelators, which may be in relatively high concentration are used to etch metal films. In various alternative embodiments new chelators, developed by tailoring known chelators to target specific metals, are used to etch metal films.

In the following description, numerous specific details are set forth. However, it is understood that embodiments of the invention may be practiced without these specific details. In other instances, well-known circuits, structures and techniques have not been shown in detail in order not to obscure the understanding of this description.

Reference throughout the specification to “one embodiment” or “an embodiment” means that a particular feature, structure, or characteristic described in connection with the embodiment is included in at least one embodiment of the present invention. Thus, the appearance of the phrases “in one embodiment” or “in an embodiment” in various places throughout the specification are not necessarily all referring to the same embodiment. Furthermore, the particular features, structures, or characteristics may be combined in any suitable manner in one or more embodiments.

Moreover, inventive aspects lie in less than all features of a single disclosed embodiment. Thus, the claims following the Detailed Description are hereby expressly incorporated into this Detailed Description, with each claim standing on its own as a separate embodiment of this invention.

Chelating agents are organic compounds that bind with metal atoms or ions to form highly soluble structures composed of a central metal atom or ion surrounded by a number of negatively charged ions or neutral ligands/substituents. The resulting compound is referred to as chelate.

Chelating agents are known in the art for a variety of uses including removing metallic impurities in semiconductor device manufacturing processes. After various process steps in IC device manufacturing, there may be minor contamination due to stray metal atoms on the wafer. One method for removing these impurities is to perform a non-intrusive wet chemistry cleaning using chelating agents in the chemistry. The chelating agents bond to the stray metal atoms and the chelates thus formed are sequestered from the wafer and held in solution.

Typically the chelating agents are selected to bind to 15-20 of the most common metal contaminants in the semiconductor manufacturing process and in this way provide thorough cleaning of the wafer. When used for such a cleaning process, chelating agents are used in concentration ranging from approximately 0.01-0.1 moles/liter. This is sufficient to remove virtually all of the stray metal atoms contaminating the wafer.

In accordance with one embodiment of the invention chelating agents in higher concentration can be used to etch metal or metal-based films in order to selectively etch the metal films while leaving intact other non-metal films. The use of chelating agents to etch the metal film avoids the destruction or degradation of the non-metal films. The redepositing of metal is also avoided due to the chelation effect (solubility constant invoked by entropic favorability) through which the metal atoms or ions are held in solution.

Process

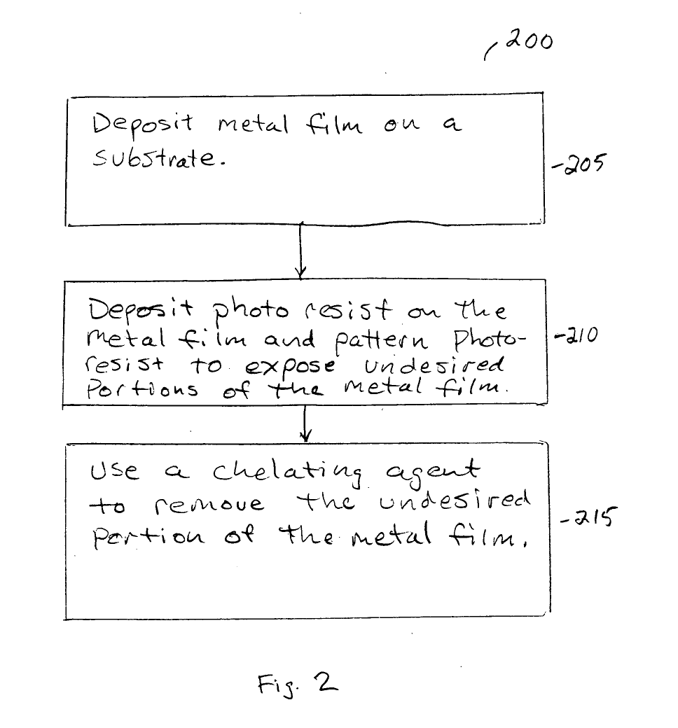

FIG. 2 illustrates a process for etching metal and metal-based films in accordance with one embodiment of the invention. Process 200, shown in FIG. 2, begins with operation 205 in which a metal or metal-based film is deposited on a substrate. The film may be any of a number of metal or metal-based films used in frontend or backend IC manufacturing processes including for example, copper, aluminum, tantalum, tantalum nitride, halfnium oxide, or various other metals and metal alloys.

At operation 210 a photoresist is deposited upon the metal film and patterned to expose undesired portion of the metal film. For alternative embodiments various other methods, as known in the art, may be employed to expose the undesired portion of the metal film to etching while masking (protecting from etching) the desired portion of the film.

At operation 215 a wet chemistry including chelating agents is applied to etch the metal layer. In accordance with one embodiment the concentration of chelating agents in aqueous solution ranges from approximately 0.5-5 moles/liter.

Use of the chelating agent to etch the metal film, as opposed to prior art solutions, avoids the destruction or degradation of the non-metal films on the wafer. However all of the metal films are now susceptible to etching from the chelating agents.

In accordance with one embodiment of the invention a chelating agent is tailored to bind with atoms of a specific metal or metal alloy in order to selectively etch particular metals or allows while leaving intact other metal films as well as the non-metal films.

Certain chelating agents can be tailored to target specific metals. For example, chelating agents have a known use in the medical treatment of metal poisoning (e.g., lead poisoning). In order to avoid stripping all metals from the patient, chelating agents are tailored to specifically target lead.

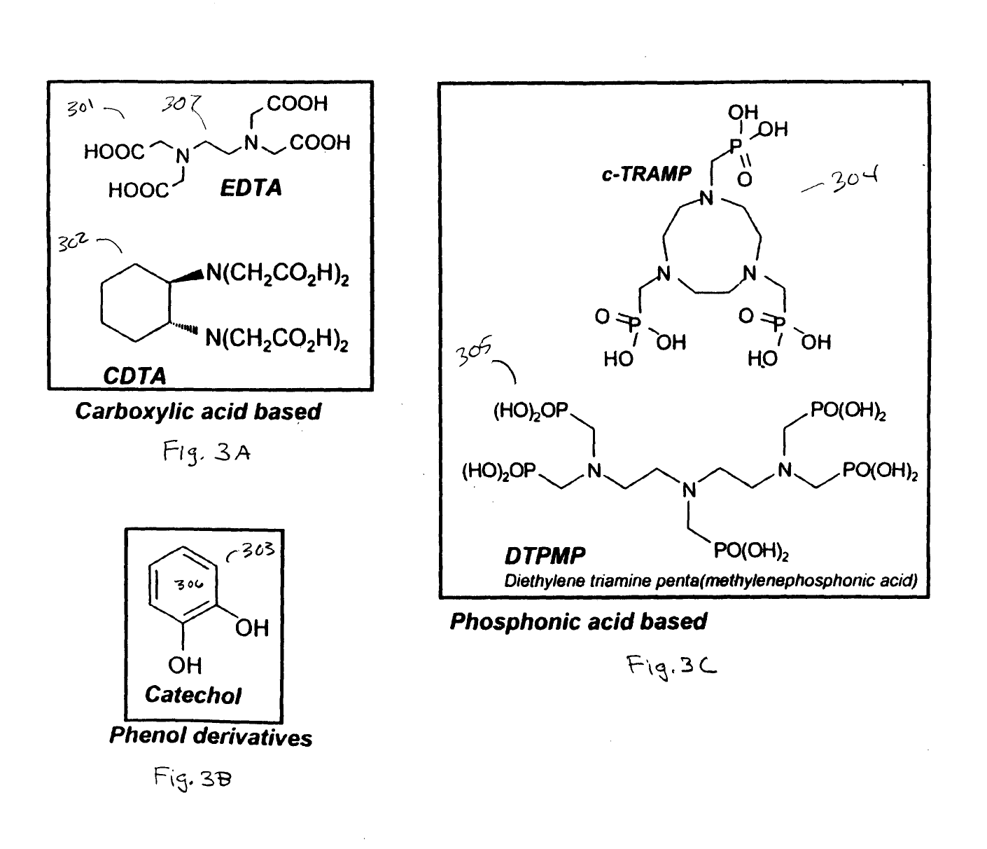

FIGS. 3A-3C illustrate various types of hexa-dentate (having six bonding atoms) chelating agents. FIG. 3A illustrates carboxylic acid based chelating agents 301 (EDTA) and 302 (CDTA). FIG. 3B illustrates a phenol derivative chelating agent 303 (catechol). FIG. 3C illustrates phosphonic acid-based chelating agents 304 (c-tramp) and 305 (DTPMP).

In accordance with one embodiment of the invention a chelating agent is tailored to bind with specific metals or alloys to provide selective etching of metal films. In tailoring the chelating agents, there are portions of the molecule that can be modified to effect selectivity. Such portions include the aryl or alkyl components of the molecule, for example, the carbon atoms, shown for example as carbon atom 307 of the EDTA molecule of FIG. 3A and the aryl group 306 of the catechol molecule of FIG. 3B. Other portions of the molecule cannot be modified as they are necessary to provide the chelate effect.

Multiple tailored chelating agents, each tailored to target a specific metal may be sued in conjunction to target a specific alloy. For such an embodiment, the chelating agents may be used in proportion to the proportion of the respective metals of the alloy.

In accordance with another embodiment a chelating agent is made to target specific metals or alloys by varying the media in which the chelating agent is employed. In accordance with alternative embodiments the chelating agents may be employed I-n an acid solution, a base solution, a solvent solution, or a de-ionized water (DIW) solution.

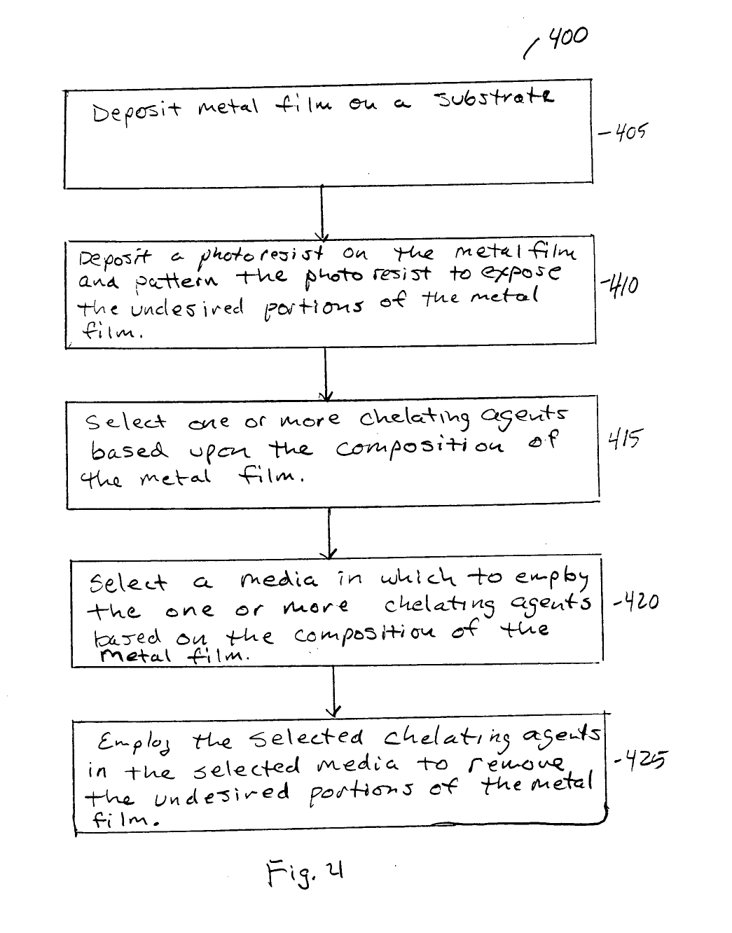

FIG. 4 illustrates a process in which a metal film is etched using one or more chelating agents in accordance with one embodiment of the invention. Process 400, shown in FIG. 4, begins with operation 405 in which a metal film is deposited upon a substrate.

At operation 410 a photoresist is deposited upon the metal film and patterned to expose undesired portion of the metal film.

At operation 415 one or more chelating agents are selected based upon the composition of the metal film. The chelating agents are chelating agents specifically tailored to bind with the particular metal or metals of the metal film.

At operation 420 a media in which to employ the one or more chelating agents is selected based upon the composition of the metal layer.

At operation 425 the selected chelating agents are employed in the selected media to to etch the metal layer.

Embodiments of the invention include various operations. Many of the methods are described in their most basic form, but operations can be added to or deleted from any of the methods without departing from the basic scope of the invention. For example, in reference to process 400, described above in reference to FIG. 4, operation 415 may be modified to selection of a generic chelating agent or operation 420 may be omitted altogether while still providing etching selectivity of the metal film.

While the invention has been described in terms of several embodiments, those skilled in the art will recognize that the invention is not limited to the embodiments described, but can be practiced with modification and alteration within the spirit and scope of the appended claims. The description is thus to be regarded as illustrative instead of limiting.

1. A method comprising:
depositing a film on a substrate, the film containing metal;
masking a desired portion of the film leaving an undesired portion of the film exposed; and
using a chelating agent to remove the undesired portion of the film.

2. The method of claim 1 wherein the film is a film selected from the group consisting of a metal film and a metal-based film.

3. The method of claim 2 wherein the chelating agent does not impair a non-metal film previously deposited upon the substrate.

4. The method of claim 2 wherein masking the desired portion of the film includes depositing a photoresist on the metal film and patterning the photoresist to mask the desired portion of the film and expose the undesired portion of the film.

5. The method of claim 2 wherein chelating agent is employed in a solution at a concentration ranging from 0.5-5 moles/liter.

6. The method of claim 5 wherein the chelating agent is employed in a solution selected from the group consisting of an acidic solution, a basic solution, a solvent solution, and a de-ionized water solution.

7. The method of claim 2 wherein the chelating agent is selected based upon the composition of the film.

8. The method of claim 6 wherein the solution is selected based upon the composition of the film.

9. An etchant comprising:
a liquid media; and
a chelating agent dissolved in the liquid media, the chelating agent tailored to target a specific metal, a concentration of the chelating agent in the liquid media sufficient to etch a film composed of the specific metal.

10. The etchant of claim 9 wherein the concentration of the chelating agent in the liquid media is in a range of approximately 0.5-5 moles/liter.

11. The etchant of claim 9 wherein the liquid media is a liquid media selected from the group consisting of an aqueous acid media with oxidant, an aqueous acid media without oxidant, an aqueous basic media with oxidant, an aqueous basic media without oxidant, and a solvent media without oxidant having a pH of approximately seven.

12. The etchant of claim 9 further comprising:
one or more additional chelating agents dissolved in the liquid media, each of the additional chelating agents tailored to target an additional specific metal.

13. A method comprising:
depositing a metallic film on a substrate, the metallic film containing one or more specific metals;
depositing a layer of photoresist on the metallic film;
patterning the photoresist such that a desired portion of the metallic film is masked and an undesired portion of the metallic film is exposed;
selecting one or more chelating agents based upon the one or more specific metals contained in the metallic film;
using the one or more chelating agents to remove the undesired portion of the metallic film.

14. The method of claim 13 further comprising:
selecting a media in which to employ the one or more chelating agents based upon the one or more specific metals contained in the metallic film.

15. The method of claim 13 wherein the one or more chelating agents do not impair a second metallic film that does not contain the one or more specific metals contained in the metallic film.

16. The method of claim 13 wherein the one or more chelating agents are employed in a solution at a concentration ranging from approximately 0.5-5 moles/liter.

17. The method of claim 14 wherein the one or more chelating agents are employed in a solution selected from the group consisting of an acidic solution, a basic solution, a solvent solution, and a de-ionized water solution.

18. A method comprising:
depositing a metallic film on a substrate, the metallic film containing one or more specific metals;
depositing a layer of photoresist on the metallic film;
patterning the photoresist such that a desired portion of the metallic film is masked and an undesired portion of the metallic film is exposed;
selecting a media in which to employ one or more chelating agents based upon the one or more specific metals contained in the metallic film;
employing the one or more chelating agents to remove the undesired portion of the metallic film.

19. The method of claim 18 further comprising:
selecting the one or more chelating agents based upon the one or more specific metals contained in the metallic film.

20. The method of claim 19 wherein the media is a liquid media selected from the group consisting of an aqueous acid media with oxidant, an aqueous acid media without oxidant, an aqueous basic media with oxidant, an aqueous basic media without oxidant, and a solvent media without oxidant having a pH of approximately seven.

21. The method of claim 18 wherein the one or more chelating agents are employed in a solution at a concentration ranging from approximately 0.5-5 moles/liter.
